(19) United States
(12) Patent Application Publication
(10) Pub. No.: US 2013/0186340 A1
(43) Pub. Date: Jul. 25, 2013

(54) Vacuum Film Forming Apparatus

(71) Applicant: ULVAC, INC., Kanagawa (JP)

(72) Inventors: Miki Omori, Kanagawa (JP); Tetsuji Kiyota, Kanagawa (JP); Yuuichi Tachino, Kanagawa (JP); Masashi Kubo, Kanagawa (JP)

(73) Assignee: ULVAC, INC., Kanagawa (JP)

(21) Appl. No.: 13/735,623

(22) Filed: Jan. 7, 2013

(30) Foreign Application Priority Data
Jan. 25, 2012 (JP) 2012-012749

(51) Int. Cl. C23C 16/455

(52) U.S. Cl. CPC C23C 16/45563
USPC 118/728

(57) ABSTRACT

A stage holds the substrate inside the vacuum chamber, gas supply device alternately supplies gases to the substrate, and exhaust device exhausts gases inside the vacuum chamber. The gas supply device has at least one ejection nozzle, disposed on one side of the stage, for ejecting the gases from one side of the substrate to the other side thereof and also along an upper surface of the substrate. In this case, that surface side of the substrate held by the stage on which the thin film is formed is defined as the upper side. The exhaust device includes: an exhaust port disposed to open through a lower wall of the vacuum chamber on the other side of the stage; an exhaust chamber disposed under the vacuum chamber in communication with the exhaust port; and a vacuum pump connected to the exhaust chamber to evacuate the exhaust chamber.

### BACKGROUND OF THE INVENTION

1. Field of the Invention

The present invention relates to a vacuum film forming apparatus in which two kinds or more raw gases are alternately supplied to a substrate which is disposed inside a vacuum chamber and which is an object on which a film is formed, thereby forming (or depositing) the predetermined thin film by chemical reaction.

2. Background of the Related Art

In the manufacturing processes of the semiconductor devices, there is a film forming process in which a predetermined thin film is formed on a substrate such as a wafer and the like which is an object on which a film is formed. In this film forming process, it is required to carry out the film formation at a low temperature with a recent trend toward further miniaturization of the semiconductor devices. For this reason, much attention has been paid to the film forming method making use of an atomic layer deposition (ALD) method which has characteristics of lowering the thermal history, good step coverage, and the like.

There is known, e.g., in patent document 1, a vacuum film forming apparatus which puts the above film forming method into practice. The apparatus in question has a vacuum chamber having a heater for heating the inside of the vacuum chamber. At an upper portion of the vacuum chamber, there is provided a gas introduction port. To this gas introduction port is respectively connected, through a change-over valve, a plurality of pipes which are provided for each of the gases. Further, in the upper space of the vacuum chamber there is provided a shower head which is in communication with the gas introduction port. In a manner to lie opposite to the shower head, there is provided a stage which holds the substrate. At the bottom portion of the vacuum chamber there is formed an exhaust port which is in communication with the vacuum pump in order to exhaust the gas inside the vacuum chamber.

Then, a first raw gas is supplied to the surface of the substrate to chemically adsorb the first raw gas onto the surface of the substrate, thereby forming a layer of atoms of the first raw gas. Then, after having replaced the gas atmosphere on the surface of the substrate by an inert gas, a second raw gas is supplied to the surface of the substrate to thereby cause the second raw gas to react with the first raw gas that has already been adsorbed onto the surface of the substrate. The layer of the atoms of the second raw gas is thus formed. Then, after having further replaced the gas atmosphere on the surface of the substrate with the inert gas, the first raw gas is adsorbed once again. Like the case as noted above, the second raw gas is once again supplied after replacing. By repeating these series of operations, two kinds or more of the raw gases are alternately supplied to thereby form predetermined thin films through chemical reactions.

However, in the above-mentioned conventional vacuum film forming apparatus, the raw gases are supplied in a direction perpendicular to the surface of the substrate, i.e., to the film forming surface of the substrate. Therefore, there is a problem in that it is difficult to cause the raw gases to be effectively adsorbed onto the entire film forming surface of the substrate. As a solution, it is conceivable to employ the following arrangement, namely, a gas supply means is arranged to supply raw gases by ejecting them from one side of the film forming surface of the substrate toward the other side thereof along the surface of the substrate, and is further arranged to evacuate the raw gases and the like that have been introduced into the vacuum chamber from the other side. In this case, there will be the need to extend sidewise, from the side wall of the vacuum chamber, the parts such as discharge pipes, and the like which are communicated with a change-over valve and pipes as a gas supply means and the vacuum pump as an exhaust means. This results in a problem in that, not only becomes the footprint of the apparatus larger but also, in some cases, the apparatus cannot be used, due to restrictions by these parts, as the film forming module for a cluster tool which is provided with a central transfer chamber.

### PRIOR ART LITERATURE

### Patent Document

[Patent Document] JP-A-2003-318174

### SUMMARY

### Problems that the Invention is to Solve

In view of the above points, this invention has a problem of providing a vacuum film forming apparatus which can prevent the footprint of the apparatus itself from getting larger without impairing the function in that the raw gases can be effectively adsorbed onto an entire film forming surface of the substrate.

### Means for Solving the Problems

In order to solve the above-mentioned problems, according to this invention, there is provided a vacuum film forming apparatus in which two kinds or more raw gases are alternately supplied to a substrate which is disposed inside a vacuum chamber and which is an object on which a film is formed, thereby forming a predetermined thin film by chemical reaction. The apparatus comprises: a stage for holding the substrate inside the vacuum chamber; gas supply means for alternately supplying gases to the substrate; and exhaust means for exhausting gases inside the vacuum chamber. The gas supply means has at least one ejection nozzle, disposed on one side of the stage, for ejecting the gases from one side of the substrate to the other side thereof and also along an upper surface of the substrate, in which that surface side of the substrate held by the stage on which the thin film is formed is defined as the upper side. The exhaust means includes: an exhaust port disposed to open through a lower wall of the vacuum chamber on the other side of the stage; an exhaust chamber disposed under the vacuum chamber in communication with the exhaust port; and a vacuum pump connected to the exhaust chamber so as to evacuate the exhaust chamber.

According to this invention, by means of the ejection nozzle that is disposed on one side of the stage, a predetermined gas is supplied from said one side of the substrate toward the other side of the substrate and also along the upper surface of the substrate. Further, by providing, on the other side of the stage, the exhaust port that is in communication with the exhaust chamber which becomes lower in pressure than the pressure in the vacuum chamber, the gas passing through the substrate is positively exhausted though the exhaust port into the exhaust chamber. Therefore, the raw gas can be effectively adsorbed onto the entire film forming surface of the substrate. In this case, the exhaust chamber is disposed under the vacuum chamber and the ejection nozzles are disposed inside the vacuum chamber so that the gas supply pipe to supply the predetermined gas to the ejection nozzles can be connected to the vacuum chamber from the bottom side of the vacuum chamber. Therefore, there is no need of mounting the piping, exhaust pipes and their parts in a manner to extend sidewise beyond the wall surfaces of the vacuum chamber. As a result, the footprint of the apparatus will not become large and, in addition, even in case this invention is applied to the film forming module for cluster tool, there will be no particular restrictions to such application.

Further, according to this invention, preferably, the ejection nozzle comprises: a base portion which is vertically disposed at a lower surface of the stage; and a nozzle portion which is continuously bent from the base portion toward said one side of the stage. The nozzle portion has a length equivalent to or larger than a maximum length of the substrate as seen from the nozzle portion and has, on that side of the nozzle portion which faces the stage, a plurality of ejection holes arrayed in a longitudinal direction of the nozzle portion at a predetermined distance from one another. Further, preferably, the exhaust port has a length equivalent to or larger than the maximum length of the substrate as seen from the nozzle portion. According to this arrangement, since the gas flows uniformly over the entire film forming surface of the substrate, the raw gas can be adsorbed onto the entire film forming surface of the substrate. In addition, the gas that cannot be adsorbed onto the film forming surface can be exhausted right after passing through the substrate.

Here, in case two kinds or more raw gases are alternately supplied to the substrate which is disposed inside the vacuum chamber and which is the object on which a film is formed as described above, thereby forming a predetermined thin film by chemical reactions, the productivity can be improved when the volume of the vacuum chamber is made small. This applies because the time for exhausting gases can be shortened when consideration is made of the fact that the previous gas remaining in the vacuum chamber must be exhausted at the time of switching the kind of gases. Further, by reducing the volume of the vacuum chamber, there can be reduced the amount of gases. On the other hand, if the volume of the vacuum chamber is made too small, it becomes difficult to transfer the substrate into or out of the stage by means of vacuum robots. As a solution, preferably, the vacuum film forming apparatus advantageously further comprises: a vertical pair of upper partition wall and a lower partition wall disposed inside the vacuum chamber; drive means for relatively moving the upper partition wall and the lower partition wall toward and away from each other; and a circumferential side wall disposed along a circumference of at least one of the upper partition wall and the lower partition wall so as to define, when the upper partition wall and the lower partition wall are relatively moved toward each other, a film forming space by enclosing the circumference of the stage inclusive of the ejection nozzle, the film forming space thus defined being isolated from, and smaller in volume than, the vacuum chamber. According to this arrangement, there is an advantage in that, while it is possible to attain a film forming space of smaller volume at the time of film formation, it is possible to secure a sufficient space for transfer work at the time of transferring of the substrate.

### BRIEF DESCRIPTION OF THE DRAWINGS

FIG. 1A is a schematic sectional view to show an arrangement of a vacuum film forming apparatus according to this invention. FIG. 1B is a sectional view taken along line Ib-Ib in FIG. 1A.

FIG. 2 is a front view of an ejection nozzle.

FIG. 3 is a block diagram to explain the supply of raw gases.

FIG. 4 is a schematic sectional view to show another arrangement of a vacuum film forming apparatus according to this invention.

### DESCRIPTION OF THE PREFERRED EMBODIMENTS

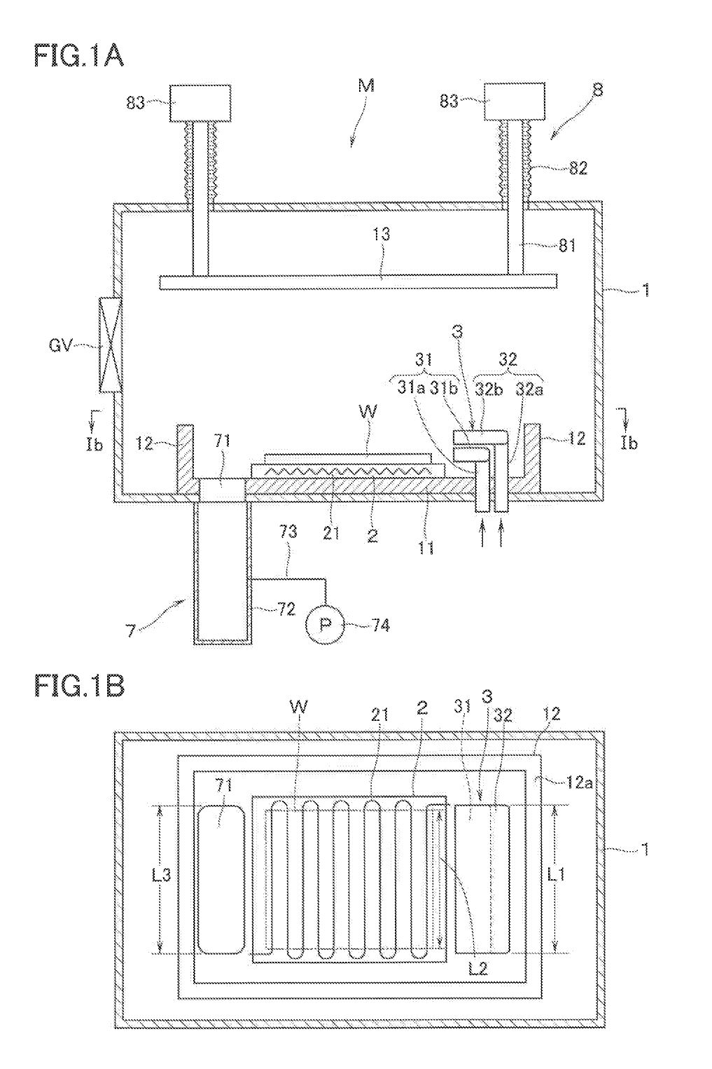

With reference to the figures, a description will now be made of a preferred embodiment of a vacuum film forming apparatus according to the this invention. In the embodiment, a film forming object (i.e., an object on which a film is formed) is selected to be a substrate W which is rectangular in shape and is made of glass. Against this substrate W a first raw gas selected out of the two kinds of gases is trimethyl aluminum (TMA), and a second raw gas selected is steam gas. Description will now be made of an embodiment of a vacuum film forming apparatus of this invention in which these raw gases are alternately supplied to form a film of aluminum oxide (Al₂O₃) on the surface of the substrate. In the following descriptions, that surface of the substrate W in FIG. 1A on which a film is formed is defined as an upper side, and the terms designating the directions such as left, right, under, front, and rear are used based on the above definition.

With reference to FIGS. 1A and 1B, reference alphabet M designates a vacuum film forming apparatus according to the embodiment of this invention. The vacuum film forming apparatus M has a vacuum chamber 1 of a predetermined volume. On the inner surface of the lower wall inside the vacuum chamber 1, there is provided a lower partition wall 11 which is smaller in area than the inner surface of the vacuum chamber 1. Along the circumference of the lower partition wall 11 there is integrally formed a circumferential side wall 12 which is projected upward. On an inner side of the circumferential side wall 12 of the lower partition wall 11 there is provided a stage 2 which holds the substrate W with the surface of film formation facing up. The stage 2 has built therein a heater 21 of electric resistance heating type so that the substrate W can be heated to a predetermined temperature at the time of film formation.

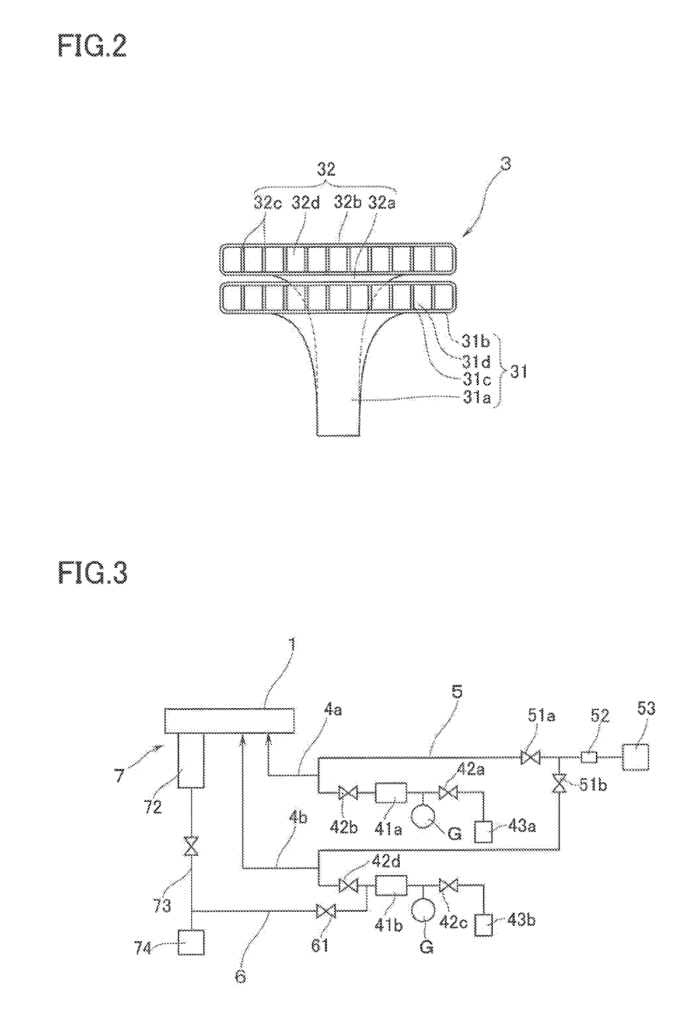

On the right side of the stage 2 and on the inside of the circumferential side wall 12 of the lower partition wall 11, there are disposed first and second ejection nozzles 31, 32 as a gas supply means 3. Both the ejection nozzles 31, 32 have substantially the same embodiment and, as shown in FIG. 2, the ejection nozzle 31 (32) has: a cylindrical base portion 31a (32a) which is vertically disposed through the lower wall of the vacuum chamber 1 and the lower partition wall 11; and a nozzle portion 31b (32b) which is formed by integrally forming the base portion 31a continuously while expanding the dimension toward the upper side, with the front end portion being bent to the side of the stage 2. The length L1 of the nozzle portion 31b in the back and forth direction is formed so as to have a length equivalent to or larger than the length L2 of that side of the substrate W which lies opposite thereto. In this case, the above-mentioned side of the substrate W becomes the largest length in the substrate W as seen from the nozzle portion 31b. In case the substrate W is circular in shape, the diameter of the substrate W becomes the largest length at that portion of the substrate W which lies opposite to the nozzle portion 31b. Further, at an end of the nozzle portion 31b on the side of the stage 2, there are disposed a plurality of partition plates 31c (32c) at an equal distance from one another in a manner to be divided into a plurality of ejection holes 31d (32d). There are thus disposed in an array a plurality of ejection holes at a predetermined distance in the longitudinal direction from one another. According to this arrangement, when the raw gas is supplied to the lower end of the base portion 31a, the raw gas is once dispersed at the upper part of this base portion 31a so as to be ejected substantially uniformly out of each of the ejection holes 31d.

Both the first and second ejection nozzles 31, 32 are so arranged that the nozzle portions 31b, 32b are disposed in an upper and lower positional relationship with each other so that each of the ejection holes 31d are positioned on the same vertical plane. In this case, each of those ejection holes 31d of the first ejection nozzle 31 which are positioned on the lower side is disposed so as to be positioned on the same plane (horizontal level) as the upper surface of the substrate W. To that portion of the base portion 31a which protrudes under the lower surface of the vacuum chamber 1, there are connected a first gas supply pipe 4a from a first raw gas supply source 43a and a second gas supply pipe 4b from a second raw gas supply source 43b.

As shown in FIG. 3, the first gas supply pipe 4a has interposed therein a buffer tank 41a, open-close valves 42a, 42b on the upstream side and on the downstream side, respectively, of the buffer tank 41a, and a vacuum gauge G, and is in communication with the gas source 43a for the first raw gas. On the other hand, the second gas supply pipe 4b has interposed therein a buffer tank 41b, open-close valves 42c, 42d on the upstream side and on the downstream side, respectively, of the buffer tank 41b, and a vacuum gauge G, and is in communication with the gas source 43b for the second raw gas. It is thus so arranged that the first raw gas and the second raw gas filled in advance in each of the buffer tanks 41a, 41b can be alternately supplied. The gas sources 43a, 43b can hold therein raw gases in the gaseous state. Alternatively, it may also be so arranged that the raw material in the liquid state or in the solid state is gasified to obtain the raw gas.

The first gas supply pipe 4a and the second gas supply pipe 4b have connected thereto an inert gas introduction pipe 5 from an inert gas source 53, the inert gas introduction pipe 5 having interposed therein open-close valves 51a, 51b and a mass flow controller 52 for introducing an inert gas such as nitrogen gas, argon gas, and the like. It is thus so arranged that, during film formation, an inert gas is constantly introduced into the vacuum chamber 1 and, after having supplied, e.g., the first raw gas to the substrate W and before supplying the second raw gas to the substrate W, the vacuum chamber 1 can be once replaced with an inert gas into an inert gas atmosphere. By the way, an arrangement may also be made that the second gas supply pipe 4b is branched between the buffer tank 41b and the open-close valve 42d on the downstream side, and that this branched bypass pipe 6 is connected to an exhaust chamber, to be described hereinafter, via the open-close valve 61.

On the left side of the stage 2 and on the inside of the circumferential side wall 12 of the lower partition wall 11, there is provided an exhaust port 71, as an exhaust means 7, which opens through the lower wall of the vacuum chamber 1 and the lower partition wall 11. The length L3 in the back and forth direction of the exhaust port 71 is formed so as to have a length equivalent to or larger than the length L2 of one side of the substrate W that lies opposite thereto. This exhaust port 71 is in communication with an exhaust chamber 72 which is disposed on an outside of the lower wall of the vacuum chamber 1. The exhaust chamber 72 has connected thereto a vacuum pump 74 through another exhaust pipe 73. As the vacuum pump 74 there is employed a known one such as a turbo molecular pump, a rotary pump, and the like. Further, the exhaust pipe 73 may be provided with a regulating valve for regulating the exhaust speed. In addition, as the exhaust chamber 72 there is utilized one which is made of a cylindrical member, and the exhaust pipe 73 is suspended so as to be extended in the vertical direction. In this case, the volume of the exhaust chamber 72 is determined considering the gas flow rate and the like.

At an upper portion inside the vacuum chamber 1 there is provided an upper partition wall 13 which lies opposite to the lower partition wall 11. The upper partition wall 13 is suspended by a plurality of drive shafts 81 which are disposed by penetrating through the upper wall of the vacuum chamber 1, and has built therein a heater (not illustrated). Bellows 82 is inserted onto an outside of that portion of the drive shaft 81 which is elongated outside the vacuum chamber 1, and is connected to the drive means 83 such as a linear motion motor and the like. By this drive means 83 the upper partition wall 13 can be vertically moved between the following two positions, i.e.: a transfer position in which the upper partition wall 13 is siding (standing-by) on the upper side inside the vacuum chamber 1 to thereby secure sufficient space for transfer work at the time of transferring of the substrate W; and a film forming position in which the circumferential portion of the upper partition wall 13 is in close contact with the upper surface of the circumferential side wall 12 such that the circumference of the stage 2 inclusive of the ejection nozzles 31, 32 and the exhaust port 71 are enclosed (or confined) into a film forming space that is isolated from the vacuum chamber 1 in a volume smaller than the volume of the vacuum chamber 1. By the way, in order to transfer the substrate W into, and out of, the stage 2, a gate valve GV is disposed on a side surface of the vacuum chamber 1. The stage 2 is provided with lift pins (not illustrated) that lift the substrate W off from the stage so that the substrate W can be transferred by means of a transfer robot having a robot hand (not illustrated).

Now, a description will be made of the film forming processing on the substrate W by the vacuum film forming apparatus M of this embodiment. In a state as shown in FIG. 1A, the vacuum film forming apparatus M is in a stand-by state in which: all the open-close valves 42a-42d are closed; the upper partition wall 13 is in a transfer position; and the inside of the film forming apparatus M is evacuated to a predetermined pressure by means of the vacuum pump 74. Then, the substrate W is transferred by a transfer robot (not illustrated) to a position right above the stage 2 and is handed over to the lift pins, whereby the substrate W is placed in position onto the stage 2. In this case, it is also possible to suck the substrate W by an electrostatic chuck and the like. Once the substrate W is placed in position onto the stage 2, the upper partition wall 13 is lowered by the drive means 83 to the film forming position. At this time, the buffer tanks 41a, 41b are respectively filled with the first raw gas and the second raw gas by opening only the open-close valves 42a, 42c. When the measured value of the vacuum gauge G has reached a predetermined value, both the open-close valves 42a, 42c are closed.

When the film forming is started, the open-close valve 42b on the downstream side and the open-close valves 51a, 51b for inert gas are opened to thereby supply the surface of the substrate W with first raw gas inside the buffer tank 41a and the inert gas. This first raw gas gets chemically adsorbed to the processing surface to thereby form a layer of atoms of the first raw gas. When the first raw gas inside the buffer tank 41a is supplied to the surface of the substrate W, only the open-close valve 42b on the downstream side is closed and the gas atmosphere on the surface of the substrate W is replaced with the inert gas. Then, once the gas atmosphere on the surface of the substrate W has been replaced by the inert gas, the open-close valve 42d on the downstream side is opened to thereby supply the second raw gas inside the buffer tank 41b and the inert gas to the surface of the substrate W, to react the first reaction gas adsorbed onto the surface of the substrate W, thereby forming a layer of atoms of the second raw gas. At this time, the buffer tank 41a is filled with the first raw gas by opening only the upstream side open-close valve 42a. When the measured value of the vacuum gauge G has reached a predetermined value, the open-close valve 42a is closed. By repeating these series of operations, two kinds or more raw gases are alternately supplied to thereby form a film of an aluminum oxide by chemical reaction.

According to the above-mentioned embodiment, the ejection nozzles 31, 32 are disposed on said one side of the stage 2 so as to supply a predetermined gas from the said one side of the substrate W toward the other side along the upper surface of the substrate W. Further, the exhaust port 71 which is in communication with the exhaust chamber 72 which becomes a lower pressure than the pressure in the vacuum chamber 1, is disposed on the other side of the stage 2 so that the gas passing along the substrate W is positively exhausted through the exhaust port 71 into the exhaust chamber 72. Therefore, the raw gas can be effectively adsorbed over the entire film formation surface of the substrate W. In this case, the arrangement is made such: that the exhaust chamber 72 is disposed under the vacuum chamber 1; that the ejection nozzles 31, 32 are disposed inside the vacuum chamber 1; and that the gas supply pipes 4a, 4b supply a predetermined gas to the ejection nozzles 31, 32 can be connected from the bottom side to the vacuum chamber 1. Therefore, there is no need of mounting the piping and the parts such as discharge pipes and the like so as to be elongated beyond the side surface of the vacuum chamber 1, whereby the footprint of the apparatus will not be large and whereby there is no particular restriction in case they have to be made a film forming module for cluster tool.

Further, by arranging the ejection nozzles 31, 32 as well as the exhaust means 7 as described above, since the gas can flow uniformly over the entire surface of the substrate W, the raw gas can be caused to get adsorbed onto the entire film forming surface of the substrate W. In addition, as soon as the gas that has not been adsorbed on the film forming surface flows past the substrate W, the raw gas can immediately be exhausted.

In addition, by providing the vertically moveable upper partition wall 13 and the lower partition wall 11 inside the vacuum chamber 1, the film forming space which is small in volume can be attained at the time of film forming, thereby the time for exhausting gases can be shortened and the amount of gases to be consumed can be reduced. On the other hand, at the time of transferring of the substrate W, sufficient transfer space can advantageously be secured.

A description has so far been made of an embodiment of this invention, but this invention is not limited to the above. In the above embodiment, a description was made of an example in which the ejection holes 31d, 32d which are equivalent to or more of the maximum length of the substrate W were disposed so as to supply raw gas to an entire film forming surface of the substrate W. This invention is however not limited thereto. For example, a plurality of gas pipes may be disposed in line with one another in the lengthwise direction of the substrate W. Or else, at that end of the nozzle portions 31b, 32b which lies on the side of the stage 2, there may be provided a plate member having perforations arrayed in the longitudinal direction at an equal distance from one another so that a plurality of ejection holes are arrayed at a predetermined distance from one another. Alternatively, the exhaust port 71 may be constituted by a plurality of exhaust ports.

Still furthermore, a description has so far been made of an example in which two ejection nozzles are disposed to introduce two kinds of raw gases. However, this invention is not limited thereto. It may also be so arranged that a plurality of raw gases are introduced with a single ejection nozzle. Further, a description has been made of an example of the upper partition wall 13 which is made up of a plate member so as to be movable in the vertical direction. This invention is, however, not limited thereto. For example, the circumferential side wall may be formed in the lower peripheral surface of the upper partition wall 13. In this case, the bottom wall of the vacuum chamber 1 may be provided with a function as the lower partition wall 11, and the lower partition wall 11 may accordingly be omitted.

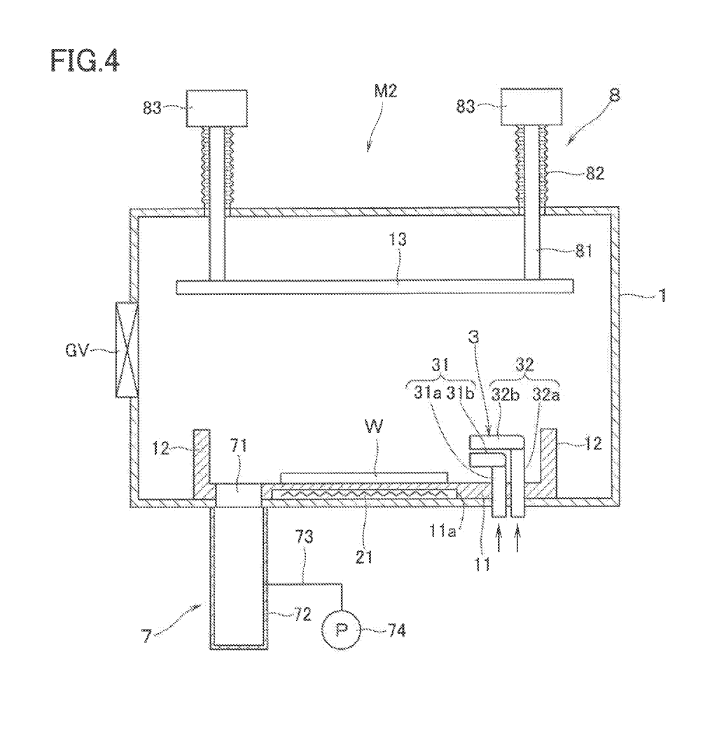

In the above embodiment, a description was made of an example in which the substrate W is held by the stage 2 disposed on the lower partition wall 11, but the substrate W may be directly held by the lower partition wall 11 serving as a stage, as shown in FIG. 4. In this case, a heater 21 may be disposed between the lower partition wall 11 and the bottom wall of the vacuum chamber 1. The vacuum film forming apparatus M2 has the heater 21 disposed in a concave portion 11a formed in the lower surface of the lower partition wall 11. The substrate W is not limited to be made of glass, but the substrate W may be made of, for example, silicon. In this case, the substrate W may be transferred to the stage 2 or the lower partition wall 11 in a state of being supported by a transfer tray.

### Explanation of Marks

M . . . vacuum film forming apparatus 1 . . . vacuum chamber 11 . . . lower partition wall (stage) 2 . . . stage 3 . . . gas supply means 31, 32 . . . ejection nozzles 7 . . . exhaust means 71 . . . exhaust port 72 . . . exhaust chamber 74 . . . vacuum pump

1. A vacuum film forming apparatus in which two kinds or more raw gases are alternately supplied to a substrate which is disposed inside a vacuum chamber and which is an object on which a film is formed, thereby forming a predetermined thin film by chemical reaction, the apparatus comprising:
a stage for holding the substrate inside the vacuum chamber;
gas supply means for alternately supplying gases to the substrate;
exhaust means for exhausting gases inside the vacuum chamber,
wherein the gas supply means has at least one ejection nozzle, disposed on one side of the stage, for ejecting the gases from one side of the substrate to the other side thereof and also along an upper surface of the substrate, that surface side of the substrate held by the stage on which the thin film is formed being defined as the upper side, and
wherein the exhaust means includes:
an exhaust port disposed to open through a lower wall of the vacuum chamber on the other side of the stage;
an exhaust chamber disposed under the vacuum chamber in communication with the exhaust port; and
a vacuum pump connected to the exhaust chamber so as to evacuate the exhaust chamber.

2. The vacuum film forming apparatus according to claim 1, wherein the ejection nozzle comprises: a base portion which is vertically disposed at a lower surface of the stage; and a nozzle portion which is continuously bent from the base portion toward said one side of the stage,
wherein the nozzle portion has a length equivalent to or larger than a maximum length of the substrate as seen from the nozzle portion and has, on that side of the nozzle portion which faces the stage, a plurality of ejection holes arrayed in a longitudinal direction of the nozzle portion at a predetermined distance from one another.

3. The vacuum film forming apparatus according to claim 1, wherein the exhaust port has a length equivalent to or larger than the maximum length of the substrate as seen from the nozzle portion.

4. The vacuum film forming apparatus according to claim 1, further comprising:
a vertical pair of upper partition wall and a lower partition wall disposed inside the vacuum chamber;
drive means for relatively moving the upper partition wall and the lower partition wall toward and away from each other; and
a circumferential side wall disposed along a circumference of at least one of the upper partition wall and the lower partition wall so as to define, when the upper partition wall and the lower partition wall are relatively moved toward each other, a film forming space by enclosing a circumference of the stage inclusive of the ejection nozzle, the film forming space thus defined being isolated from, and smaller in volume than, the vacuum chamber.

5. The vacuum film forming apparatus according to claim 2, further comprising:
a vertical pair of upper partition wall and a lower partition wall disposed inside the vacuum chamber;
drive means for relatively moving the upper partition wall and the lower partition wall toward and away from each other; and
a circumferential side wall disposed along a circumference of at least one of the upper partition wall and the lower partition wall so as to define, when the upper partition wall and the lower partition wall are relatively moved toward each other, a film forming space by enclosing a circumference of the stage inclusive of the ejection nozzle, the film forming space thus defined being isolated from, and smaller in volume than, the vacuum chamber.

6. The vacuum film forming apparatus according to claim 3, further comprising:
a vertical pair of upper partition wall and a lower partition wall disposed inside the vacuum chamber;
drive means for relatively moving the upper partition wall and the lower partition wall toward and away from each other; and
a circumferential side wall disposed along a circumference of at least one of the upper partition wall and the lower partition wall so as to define, when the upper partition wall and the lower partition wall are relatively moved toward each other, a film forming space by enclosing a circumference of the stage inclusive of the ejection nozzle, the film forming space thus defined being isolated from, and smaller in volume than, the vacuum chamber.
